(19) United States
(12) Patent Application Publication
(10) Pub. No.: US 2026/0136687 A1
(43) Pub. Date: May 14, 2026

(54) SUBSTRATE PROCESSING METHODS

(71) Applicant: SEMICONDUCTOR COMPONENTS INDUSTRIES, LLC, Scottsdale, AZ (US)

(72) Inventor: Gabrielle ROBERT, Fishkill, NY (US)

(73) Assignee: SEMICONDUCTOR COMPONENTS INDUSTRIES, LLC, Scottsdale, AZ (US)

(21) Appl. No.: 18/946,673

(22) Filed: Nov. 13, 2024

(51) Int. Cl. H01L 27/146; H01L 21/20

(52) U.S. Cl. CPC H10F 39/026; H10P 90/1914

(57) ABSTRACT

Implementations of a method of processing a substrate may include providing a semiconductor substrate; removing a predetermined thickness of material of the semiconductor substrate at a perimeter of the semiconductor substrate; and applying an adhesive to a largest planar surface of the semiconductor substrate. The method may include applying a sealing material at the perimeter of the semiconductor substrate, and bonding an optically transmissive substrate to the semiconductor substrate using the adhesive and the sealing material.

### BACKGROUND

### 1. Technical Field

Aspects of this document relate generally to substrates, such as substrates used in image sensor packages.

### 2. Background

Various semiconductor package designs have been devised that facilitate electrical connections to a semiconductor die to a circuit or other mother board to which the package is attached. Other semiconductor package designs provide mechanical stability or protection from shock and vibration. Some semiconductor packages are formed on a wafer scale and others are formed on the semiconductor die scale.

### SUMMARY

Implementations of a method of processing a substrate may include providing a semiconductor substrate; removing a predetermined thickness of material of the semiconductor substrate at a perimeter of the semiconductor substrate; and applying an adhesive to a largest planar surface of the semiconductor substrate. The method may include applying a sealing material at the perimeter of the semiconductor substrate, and bonding an optically transmissive substrate to the semiconductor substrate using the adhesive and the sealing material.

Implementations of a method of processing a substrate may include one, all, or any of the following:

The method may include planarizing the sealing material prior to bonding the optically transmissive substrate.

The method may include thinning the semiconductor substrate to a predetermined thickness.

The method may include singulating the optically transmissive substrate and semiconductor substrate to form a plurality of image sensor packages.

The semiconductor substrate may be circular and removing a predetermined thickness of material further may include removing a width of 1 mm to 3 mm of material at the perimeter of the semiconductor substrate.

Removing the predetermined thickness of material further may include removing using sawing.

Removing the predetermined thickness of material further may include removing using etching.

Removing the predetermined thickness of material further may include removing using wet etching.

The adhesive forms a grid pattern on the largest planar surface of the semiconductor substrate.

Implementations of a method of processing a substrate may include providing a semiconductor substrate; forming a groove in the semiconductor substrate at a perimeter of the semiconductor substrate; applying an adhesive to a largest planar surface of the semiconductor substrate; applying a sealing material into the groove; and bonding an optically transmissive substrate to the semiconductor substrate using the adhesive and the sealing material.

Implementations of a method of processing a substrate may include one, all, or any of the following:

The method may include planarizing the sealing material prior to bonding the optically transmissive substrate.

The method may include thinning the semiconductor substrate to a predetermined thickness.

The method may include singulating the optically transmissive substrate and semiconductor substrate to form a plurality of image sensor packages.

The semiconductor substrate may be circular and the groove may have a width of 1 mm to 3 mm.

The adhesive may form a grid pattern on the largest planar surface of the semiconductor substrate.

Implementations of a method of processing a substrate may include providing a semiconductor substrate; cutting around a perimeter of the semiconductor substrate a predetermined distance into a largest planar surface of the semiconductor substrate; applying an adhesive to the largest planar surface of the semiconductor substrate; applying a sealing material on the perimeter of the semiconductor substrate; and bonding an optically transmissive substrate to the semiconductor substrate using the adhesive and the sealing material.

Implementations of a method of processing a substrate may include one, all, or any of the following:

The method may include thinning the semiconductor substrate to a predetermined thickness.

The method may include singulating the optically transmissive substrate and semiconductor substrate to form a plurality of image sensor packages.

The image sensor packages include one of an air gap or may be gapless image sensor packages.

The adhesive may form a grid pattern on the largest planar surface of the semiconductor substrate.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side cross sectional flow view of an implementation of a semiconductor substrate and an optically transmissive substrate during a bonding operation;

FIG. 2 is a top view of the semiconductor substrate and optically transmissive substrate of FIG. 1 during the flow of FIG. 1;

FIG. 3 is a cross sectional detail view of the edge of the semiconductor substrate and edge of the optically transmissive substrate of FIG. 1 during a curing operation;

FIG. 4 is a side view of an implementation of a semiconductor substrate following grooving of an edge of the substrate;

FIG. 5 is a side view of the semiconductor substrate of FIG. 4 following application of an adhesive thereon;

FIG. 6 is a side cross sectional view of the semiconductor substrate of FIG. 5 following application of a sealing material into the groove during a curing operation;

FIG. 7 is a side cross sectional view of the semiconductor substrate of FIG. 6 following bonding of an optically transmissive substrate;

FIG. 8 is a top view of a semiconductor substrate following formation of a groove around a perimeter of the substrate;

FIG. 9 is a top view of the semiconductor substrate of FIG. 8 following application of an adhesive thereon;

FIG. 10 is a top view of the semiconductor substrate of FIG. 9 following application of a sealing material into the groove;

FIG. 11 is a top view of the semiconductor substrate of FIG. 10 following bonding of an optically transmissive substrate; and

FIG. 12 is a side cross sectional view of a semiconductor substrate during an edge grooving operation.

### DESCRIPTION

This disclosure, its aspects and implementations, are not limited to the specific components, assembly procedures or method elements disclosed herein. Many additional components, assembly procedures and/or method elements known in the art consistent with the intended methods of processing a substrate will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such methods of processing a substrate, and implementing components and methods, consistent with the intended operation and methods.

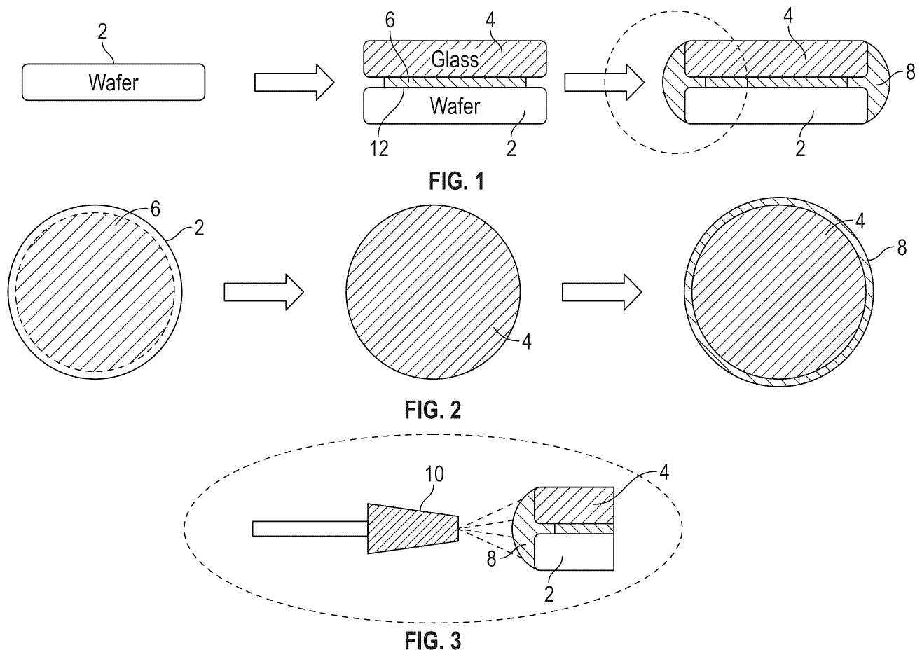

Referring to FIG. 1, an implementation of a semiconductor substrate 2 is illustrated prior to packaging processing but after formation of a plurality of semiconductor devices thereon/therein (not shown in FIG. 1). The semiconductor devices in the semiconductor substrate illustrated in FIG. 1 are image sensor devices that are designed to detect various wavelengths of electromagnetic radiation. The various wavelengths detected may be, by non-limiting example, visible light, infrared light, ultraviolet light, X-rays, gamma rays, or any other electromagnetic radiation wavelength type. The particular material of the semiconductor material may vary depending on the types of image sensor devices being formed and may be, by non-limiting example, silicon, silicon-on-insulator, silicon carbide, gallium arsenide, gallium nitride, sapphire, ruby, or any other semiconductor material type.

FIG. 1 illustrates the semiconductor substrate 2 after bonding to an optically transmissive substrate (here glass) 4 using an adhesive 6. A wide variety of adhesive could be utilizing, including, by non-limiting example, a dry film adhesive, a liquid adhesive, a polyimide, a tacky adhesive, a resin adhesive, or any other permanent adhesive type consistent with permitting electromagnetic radiation to pass through the optically transmissive substrate 4 to reach the plurality of semiconductor devices. To fill the remaining gap at the edges of the semiconductor substrate 4 and the optically transmissive substrate 4 a sealing material 8 is applied and cured using an edge sealing nozzle 10 followed by an ultraviolet light curing process as illustrated in FIG. 3. The sealing material is a heat resistant polymer in this implementation that is also ultraviolet light curable. The sequence illustrated in FIG. 2 shows a top view of the same process where the semiconductor substrate 2 is illustrated after application of the adhesive 6 to a largest planar surface 12 of the semiconductor substrate 2. The semiconductor substrate 2 is then illustrated following coupling/bonding of the optically transmissive substrate 4 with the adhesive 6. The effect of increasing the circumference/size of the bonded substrate scale system beyond the perimeter of the optically transmissive substrate 4 with the sealing material 8 is illustrated in the right-most figure in FIG. 2.

The goal of forming the edge seal is to help prevent wafer edge chipping/cracking during a subsequent wafer thinning/grinding operation. The use of the edge seal can also help produce a uniform shape to the edge of the bonded substrate scale system that accounts for incoming variations in the dimensions substrate edges. These variations in substrate edges can occur during the previous processing operations that created the plurality of semiconductor devices in the semiconductor substrate.

The method implementations illustrated in FIGS. 1-3 help create a uniform shaped edge, but they do not actually change the shape of the substrate edge itself. Furthermore, because during a subsequent thinning/grinding operation the pre-existing shape of the substrate edge remains the same or substantially the same post-grinding, any chipping that does occur remains in the substrate after the thinning process. This chipping can make wafer handling equipment that relies on edge detection or the uniform position of the edge to can experience difficulty. This problem may be particularly acute because the wafer handling equipment is unable to “see” or detect the presence of the optically transmissive substrate 4 as may be is transparent or semitransparent to many wavelengths of electromagnetic radiation. Finally, preventing running of the sealing material during the process of using the edge sealing nozzle to apply the sealing material and sealing with UV light may be difficult if the two substrates are in a horizontal orientation as illustrated in FIG. 3 during application. If the bonded substrate scale system is moved into a vertical orientation during the application of the sealing material to help minimize running of the material, additional more complex substrate transfer equipment may need to be used to move them into and out of the vertical orientation without touching the uncured material edge.

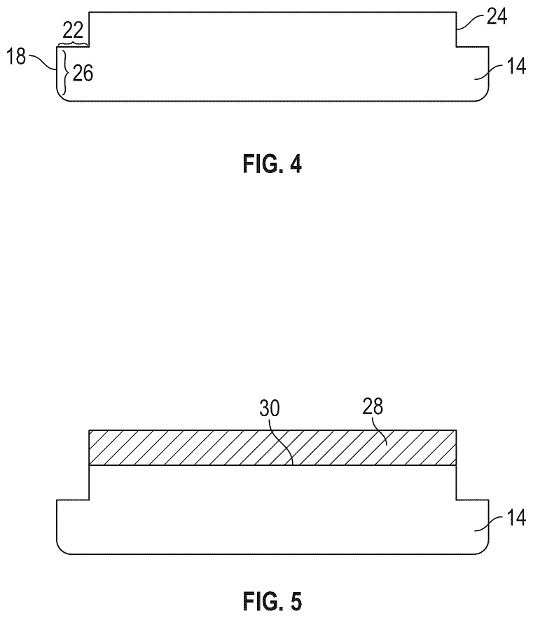

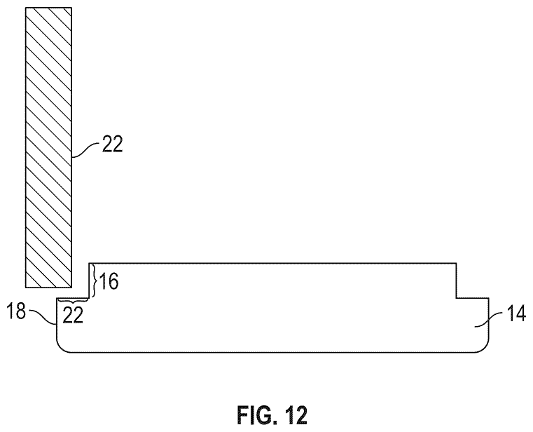

Another approach to producing a bonded semiconductor substrate with a uniform edge is illustrated in the method implementation illustrated in FIGS. 4-12. Referring to FIG. 12, a semiconductor substrate 14 like any disclosed herein is illustrated during a cutting/grooving operation where a predetermined thickness 16 of material is being removed at/along the perimeter/edge 18 of the semiconductor substrate 14. Here the material is being removed using a saw blade 20 with a desired kerf width to create a groove a desired predetermined distance/width 22 into the material of the semiconductor substrate 14 from the edge of the perimeter 18. The resulting grooved semiconductor substrate 14 is illustrated in FIG. 4.

The shape of the groove 24 may be determined by the particular process used to remove the material from the edge of the semiconductor substrate 14. Where sawing is used, the groove 24 may take the shape of a step with two substantially perpendicularly aligned edges. Where the groove is dry etched using a lithographic patterning process, the groove may have a similarly stepped shape with very precise control of the shape and without chipping present in any portion of the groove. In method implementations where the groove is wet etched following a lithographic patterning process, the shape of the groove may form a rounded step due to the isotropic nature of a wet etching process. In various method implementations the width of material removed into the semiconductor substrate/width of the groove may be between 1 mm and about 3 mm. In particular method implementation, the width 22 of the groove 24 may correspond substantially with a width of an edge exclusion region adjacent to the perimeter 18 of the semiconductor substrate 14.

In various method implementations, the depth of material removed into the semiconductor substrate 14 may be set at a predetermined value that corresponds with a desired final thickness of the semiconductor substrate 14 following a thinning operation. Because the remaining thickness 26 of the semiconductor substrate 14 is the same thickness that the thinning process will remove, any chipping that takes place during the thinning process is eliminated during the thinning process as it completes. Furthermore, the ability to etch a desired width into the semiconductor substrate gives the semiconductor substrate a controlled/desired perimeter shape after the thinning process is completed. This controlled/uniform/desired perimeter shape may be easier to detect in/work with subsequent substrate handling equipment as well.

Referring to FIG. 5, the semiconductor substrate 14 is illustrated following application of an adhesive layer 28 onto a largest planar surface 30 of the semiconductor substrate 14. While the adhesive layer 28 is illustrated as being a continuous layer across the largest planar surface 30 in this cross sectional view, in other method implementations the adhesive layer 28 may for a grid or other set of spaced apart closed shapes around the plurality of semiconductor devices on/in the largest planar surface 30. Where the adhesive layer 28 forms a grid, a plurality of gapped or air gapped image sensors are ultimately formed. Where the adhesive layer 28 is a continuous layer of adhesive, a plurality of gapless image sensors are ultimately formed. Any of the adhesive types disclosed in this document may be employed for the adhesive layer in this method implementations.

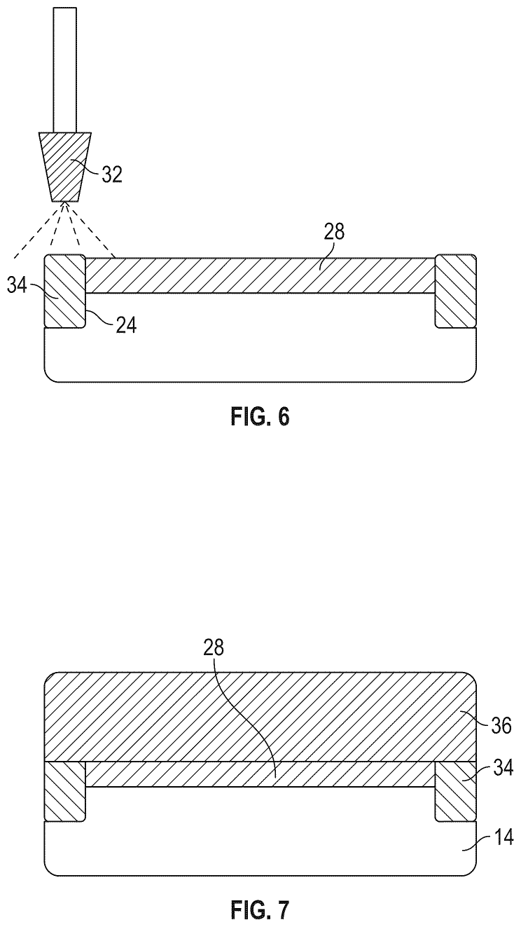

With the adhesive layer 28 in place, FIG. 6 illustrates the semiconductor substrate 14 during an edge dispensing process where nozzle 32 is dispensing sealing material 34 into the groove 24. In this implementation, a polyimide material is being dispensed into the groove but in other implementations other sealing materials could be employed, including, by non-limiting example, spin-on adhesives, resins, glues, or other thermally or UV curable adhesive materials. Because of the presence of the groove 24, the ability to dispense the sealing material 34 across the depth of the groove 24 and the thickness of the adhesive layer 28 when the semiconductor substrate 14 is in a horizontal orientation may be enhanced. In some implementations, during or immediately after dispensing, an initial curing process using heat or UV light may be carried out to get the sealing material 34 to a B-stage or other non-flowing hardness so it will remain in the groove 24 without flowing/running out.

In some method implementations, a nozzle may not be used to apply the sealing material but other processes could be employed, including, by non-limiting example, spin coating, dipping, dry film application into the groove, gravity feeding, or any other method of applying a solid or viscous material into the groove. If the material being used is curable or partially curable using UV light, the dispensing process may also include exposing the material to UV light either at the time of dispense or soon afterward.

At this point, the semiconductor substrate 14 is ready for coupling/bonding of an optically transmissive substrate 36 thereto. FIG. 7 illustrates the optically transmissive substrate 36 coupled to the semiconductor substrate 14 through the adhesive layer 28 and the sealing material 34. At this point, the semiconductor substrate 14 is ready for a thinning operation to be performed as it is now supported by the optically transmissive substrate 36. In various implementations, the material of the optically transmissive substrate may be, by non-limiting example, glass, silicon dioxide, plastic, acrylic, any combination thereof, or any other optically transmissive material type. Where the semiconductor substrate 14 was thinned prior to the formation of the groove, the formation of the groove may take the form of a full edge cut of the semiconductor substrate which creates a desired edge shape. No further thinning may then be carried out after bonding of the semiconductor substrate to the optically transmissive substrate.

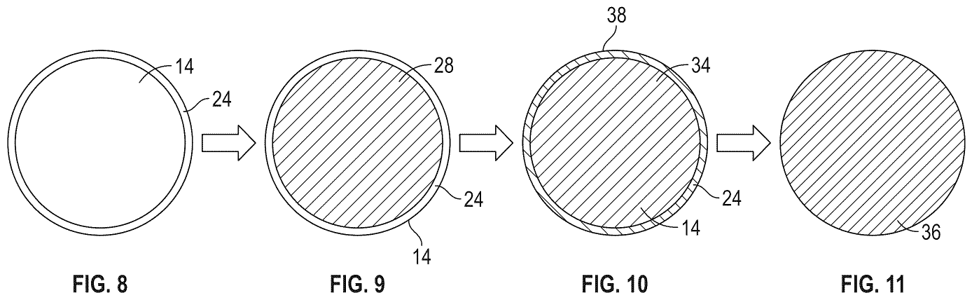

FIGS. 8-11 illustrate the process flow from a top down view rather than cross sectional view. FIG. 8 illustrates the semiconductor substrate 14 following the formation of the groove 24. This particular semiconductor substrate 14 is circular, but other closed shapes for the semiconductor substrate 14 could be utilized, particularly where etching rather than sawing is used to form the groove 24. The width of the groove 24 in this implementation is substantially the same size as the edge exclusion region of the semiconductor substrate 14 used during fabrication of the semiconductor devices included in the semiconductor substrate 14.

FIG. 9 illustrates the semiconductor substrate 14 following application of the adhesive layer 28 thereon showing how the adhesive layer 28 material is not in the groove 24. Referring to FG. 10, the semiconductor substrate 14 is illustrated following application of the sealing material 34 into the groove 24. In this implementation, the perimeter 38 of the semiconductor substrate 14 remains the same size after application of the sealing material 34 as it was at the time of formation of the groove 24.

Referring to FIG. 11, the optically transmissive substrate 36 is illustrated coupled/bonded over the semiconductor substrate using the adhesive layer 28 and the sealing material 34. Any of the optically transmissive substrate material types may be employed in this method implementation. With the optically transmissive substrate 36 in place, the semiconductor substrate is now ready for further thinning. During the coupling/bonding process, any additional curing processes/steps used to cure the adhesive layer and/or sealing material are also carried out. These processes/steps work to allow for formation of a permanent bond between the adhesive and sealing material and the material of the optically transmissive substrate and the semiconductor substrate. Where the adhesive layer takes the form of a grid as previously discussed herein, air gaps are formed/created over the various semiconductor devices included in the largest planar surface of the semiconductor substrate. Where the adhesive layer is a continuous layer as illustrated in FIGS. 9 and 10, a set of gapless image sensors are formed.

Following the thinning process where the semiconductor substrate is thinned to a desired thickness, a singulation process is used to separate the various semiconductor devices into semiconductor packages whether air gapped or gapless. In some implementations, the singulation process takes place using sawing, but other singulation processes like etching, lasering, or water jet cutting could be used in various method implementations.

The semiconductor substrate 2 illustrated in FIGS. 1 and 4 is a full thickness substrate, meaning that it is still the thickness originally used during processing through the various fabrication process steps that formed the plurality of semiconductor devices thereon/therein. However, in some method implementations, the semiconductor substrate 2 may be thinned prior to the processing operations illustrated in FIGS. 1-2. In such method implementations, this thinning takes place in lieu of any subsequent thinning processes that take place after bonding to an optically transmissive substrate. In some implementations, to aid in handling of the thinned wafer during the bonding process, an edge ring of thick or full thickness material may be retained around the semiconductor substrate to support it. In such method implementations, the method also includes cutting/singulating the edge ring following the completion of the sealing material application and the bonding process to the optically transmissive substrate.

In places where the description above refers to particular implementations of methods of processing substrates and implementing components, sub-components, methods and sub-methods, it should be readily apparent that a number of modifications may be made without departing from the spirit thereof and that these implementations, implementing components, sub-components, methods and sub-methods may be applied to other methods of processing substrates.

What is claimed is:

1. A method of processing a substrate comprising:
providing a semiconductor substrate;
removing a predetermined thickness of material of the semiconductor substrate at a perimeter of the semiconductor substrate;
applying an adhesive to a largest planar surface of the semiconductor substrate;
applying a sealing material at the perimeter of the semiconductor substrate; and
bonding an optically transmissive substrate to the semiconductor substrate using the adhesive and the sealing material.

2. The method of claim 1, further comprising planarizing the sealing material prior to bonding the optically transmissive substrate.

3. The method of claim 1, further comprising thinning the semiconductor substrate to a predetermined thickness.

4. The method of claim 1, further comprising singulating the optically transmissive substrate and semiconductor substrate to form a plurality of image sensor packages.

5. The method of claim 1, wherein the semiconductor substrate is circular and removing a predetermined thickness of material further comprises removing a width of 1 mm to 3 mm of material at the perimeter of the semiconductor substrate.

6. The method of claim 1, wherein removing the predetermined thickness of material further comprises removing using sawing.

7. The method of claim 1, wherein removing the predetermined thickness of material further comprises removing using etching.

8. The method of claim 1, wherein removing the predetermined thickness of material further comprises removing using wet etching.

9. The method of claim 1, wherein the adhesive forms a grid pattern on the largest planar surface of the semiconductor substrate.

10. A method of processing a substrate comprising:
providing a semiconductor substrate;
forming a groove in the semiconductor substrate at a perimeter of the semiconductor substrate;
applying an adhesive to a largest planar surface of the semiconductor substrate;
applying a sealing material into the groove; and
bonding an optically transmissive substrate to the semiconductor substrate using the adhesive and the sealing material.

11. The method of claim 10, further comprising planarizing the sealing material prior to bonding the optically transmissive substrate.

12. The method of claim 10, further comprising thinning the semiconductor substrate to a predetermined thickness.

13. The method of claim 10, further comprising singulating the optically transmissive substrate and semiconductor substrate to form a plurality of image sensor packages.

14. The method of claim 10, wherein the semiconductor substrate is circular and the groove has a width of 1 mm to 3 mm.

15. The method of claim 10, wherein the adhesive forms a grid pattern on the largest planar surface of the semiconductor substrate.

16. A method of processing a substrate comprising:
providing a semiconductor substrate;
cutting around a perimeter of the semiconductor substrate a predetermined distance into a largest planar surface of the semiconductor substrate;
applying an adhesive to the largest planar surface of the semiconductor substrate;
applying a sealing material on the perimeter of the semiconductor substrate; and
bonding an optically transmissive substrate to the semiconductor substrate using the adhesive and the sealing material.

17. The method of claim 16, further comprising thinning the semiconductor substrate to a predetermined thickness.

18. The method of claim 16, further comprising singulating the optically transmissive substrate and semiconductor substrate to form a plurality of image sensor packages.

19. The method of claim 18, where the image sensor packages comprise one of an air gap or are gapless image sensor packages.

20. The method of claim 16, wherein the adhesive forms a grid pattern on the largest planar surface of the semiconductor substrate.
